(19) United States
(12) Patent Application Publication
(10) Pub. No.: US 2009/0206393 A1
(43) Pub. Date: Aug. 20, 2009

(54) NONVOLATILE MEMORY ELEMENT AND METHOD OF MANUFACTURING THE SAME

(76) Inventors: Keiko Ariyoshi, Okayama-shi (JP); Akira Takashima, Fuchu-shi (JP); Shoko Kikuchi, Kawasaki-shi (JP); Koichi Muraoka, Sagamihara-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/388,040

(22) Filed: Feb. 18, 2009

(30) Foreign Application Priority Data
Feb. 19, 2008 (JP) 2008-037893

(51) Int. Cl. H01L 29/792; H01L 21/28

(52) U.S. Cl. 257/326; 438/591; 257/E29.309; 257/E21.21

(57) ABSTRACT

A nonvolatile memory element includes a semiconductor region, a source region and a drain region provided in the semiconductor region, a tunnel insulating layer provided on the semiconductor region between the source region and the drain region, a charge storage layer provided on the tunnel insulating layer, a block insulating layer provided on the charge storage layer, and a control gate electrode provided on the block insulating layer. The charge storage layer includes one of an oxide, a nitride and an oxynitride, which contains at least one material selected from the group consisting of Hf, Al, Zr, Ti and a rare-earth metal, and is entirely or partially crystallized. The block insulating layer includes one of an oxide, an oxynitride, a silicate and an aluminate, which contains at least one rare-earth metal.

### CROSS-REFERENCE TO RELATED APPLICATIONS

This application is based upon and claims the benefit of priority from prior Japanese Patent Application No. 2008-037893, filed Feb. 19, 2008, the entire contents of which are incorporated herein by reference.

### BACKGROUND OF THE INVENTION

1. Field of the Invention

The present invention relates to a nonvolatile memory element and a method of manufacturing the same, e.g., a nonvolatile memory element that stores information by injecting and removing electric charge into and from a charge storage layer, and a method of manufacturing the same.

2. Description of the Related Art

A flash memory as a kind of electrically erasable programmable read-only memory (EEPROM) that electrically writes and erases data is known as a nonvolatile semiconductor memory. Also, a flash memory using a metal oxide nitride oxide semiconductor (MONOS) memory cell transistor is known as a kind of the flash memory. This MONOS memory cell transistor has a structure suited to micropatterning because an insulating film is used as a charge storage layer.

The memory cell transistor has a gate structure in which a tunnel insulating film, charge storage layer, block insulating film, and control gate electrode are sequentially stacked on a semiconductor substrate. When a high electric field is applied between the control gate electrode and semiconductor substrate, the threshold voltage of the memory cell transistor changes because electrons injected from the semiconductor substrate into the charge storage layer are captured in traps caused by defects in the charge storage layer. Information is stored by using this change in threshold voltage. In this case, operating voltages necessary for write and erase can be reduced by applying a high voltage to the tunnel insulating film by increasing the capacitances of the charge storage layer and block insulating film. Also, leakage currents must be reduced in order to improve the holding characteristics of the electric charge captured in the charge storage layer, and efficiently perform write and erase. Therefore, the block insulating film is required to increase the capacitance and reduce the leakage currents.

Generally, silicon nitride (SiN) is mainly used as the charge storage layer of the MONOS memory cell transistor. It is also desirable to use a material having a dielectric constant higher than those of silicon oxide and silicon nitride in order to improve the charge holding characteristics and reduce the leakage currents. Furthermore, a high trap density and high heat resistance (heat tolerance) are required.

A new material to be applied to the charge storage layer is desirably adapted to the conventional memory cell transistor formation method. The conventional floating gate or MONOS memory cell transistor formation method is as follows. A gate structure is formed by sequentially depositing a tunnel insulating film, charge storage layer, block insulating film, and control gate electrode on a semiconductor substrate. An ion implantation region is formed by ion-implanting an impurity such as boron (B), phosphorus (P), arsenic (As), or antimony (Sb) in the semiconductor substrate. Finally, the ion implantation region is activated by annealing the sample. After that, a nonvolatile semiconductor memory is completed by forming an interlayer dielectric film, interconnection layer, and the like by the well-known methods.

Unfortunately, the conventional memory cell transistor fabrication includes a high-temperature annealing step performed at, e.g., 900° C. to 1,000° C. When using amorphous silicon nitride or an amorphous high-k insulating material as the charge storage layer, the high-temperature annealing causes mixing or interdiffusion of the stacked film including this amorphous insulating film. This may change the film thickness or degrade the electrical characteristics. Accordingly, it is required to form a stacked film having a high thermal stability while maintaining the structure and electrical characteristics even after the high-temperature annealing.

As a related technique of this kind, a technique that lowers the driving voltage while maintaining the retention characteristics in a SONOS memory element including a high-k insulating film is disclosed (JP-A 2005-268756 (KOKAI)).

### BRIEF SUMMARY OF THE INVENTION

According to an aspect of the present invention, there is provided a nonvolatile memory element comprising: a semiconductor region; a source region and a drain region provided in the semiconductor region; a tunnel insulating layer provided on the semiconductor region between the source region and the drain region; a charge storage layer provided on the tunnel insulating layer; a block insulating layer provided on the charge storage layer; and a control gate electrode provided on the block insulating layer. The charge storage layer includes one of an oxide, a nitride and an oxynitride, which contains at least one material selected from the group consisting of Hf, Al, Zr, Ti and a rare-earth metal, and is entirely or partially crystallized. The block insulating layer includes one of an oxide, an oxynitride, a silicate and an aluminate, which contains at least one rare-earth metal.

According to an aspect of the present invention, there is provided a nonvolatile memory element comprising: a semiconductor region; a source region and a drain region provided in the semiconductor region; a tunnel insulating layer provided on the semiconductor region between the source region and the drain region; a charge storage layer including a first insulating layer which is provided on the tunnel insulating layer and amorphous, and a second insulating layer which is granularly formed in the first insulating layer and crystallized; a block insulating layer provided on the charge storage layer; and a control gate electrode provided on the block insulating layer. The second insulating layer includes one of an oxide, a nitride and an oxynitride, which contains at least one material selected from the group consisting of Hf, Al, Zr, Ti and a rare-earth metal, and is entirely or partially crystallized. The block insulating layer includes one of an oxide, an oxynitride, a silicate and an aluminate, which contains at least one rare-earth metal.

According to an aspect of the present invention, there is provided a method of manufacturing a nonvolatile memory element, comprising: forming a tunnel insulating layer on a semiconductor region; forming a charge storage layer on the tunnel insulating layer; crystallizing the charge storage layer by performing first annealing; forming a block insulating layer on the charge storage layer; forming a control gate electrode on the block insulating layer; forming an impurity region in the semiconductor region by doping an impurity in the semiconductor region; and activating the impurity region by performing second annealing.

### BRIEF DESCRIPTION OF THE SEVERAL VIEWS OF THE DRAWING

FIGS. 1A and 1B are views illustrating sectional TEM images of a stacked gate structure according to a comparative example;

FIG. 2 is a sectional view illustrating the structure of a memory cell transistor according to the first embodiment;

FIG. 3 is a view illustrating a sectional TEM image of a stacked gate structure according to the first embodiment;

FIG. 4 is a graph illustrating the EOT change ratios before and after annealing of the first embodiment and comparative example;

FIG. 5 is a sectional view illustrating a method of manufacturing the memory cell transistor according to the first embodiment;

FIG. 6 is a sectional view illustrating a manufacturing method, which follows FIG. 5, of the memory cell transistor;

FIG. 7 is a sectional view illustrating a manufacturing method, which follows FIG. 6, of the memory cell transistor;

FIG. 8 is a sectional view illustrating a manufacturing method, which follows FIG. 7, of the memory cell transistor;

FIG. 9 is a sectional view illustrating the structure of a memory cell transistor according to the second embodiment;

FIG. 10 is a sectional view illustrating a method of manufacturing the memory cell transistor according to the second embodiment;

FIG. 11 is a sectional view illustrating a manufacturing method, which follows FIG. 10, of the memory cell transistor;

FIG. 12 is a sectional view illustrating a manufacturing method, which follows FIG. 11, of the memory cell transistor;

FIG. 13 is a sectional view illustrating the structure of a memory cell transistor according to the third embodiment;

FIG. 14 is a sectional view illustrating a method of manufacturing the memory cell transistor according to the third embodiment;

FIG. 15 is a sectional view illustrating a manufacturing method, which follows FIG. 14, of the memory cell transistor; and

FIG. 16 is a sectional view illustrating a manufacturing method, which follows FIG. 15, of the memory cell transistor.

### DETAILED DESCRIPTION OF THE INVENTION

In the conventional memory cell transistor fabrication, after a charge storage layer and block insulating film are deposited on a semiconductor substrate, the stacked film is etched. Then, an impurity is doped in the exposed semiconductor substrate in order to form source and drain regions, and activated by performing high-temperature annealing at 900° C. to 1,000° C. In this step, the amorphous charge storage layer and amorphous block insulating film cause mixing or interdiffusion, thereby changing the film thickness or degrading the electrical characteristics.

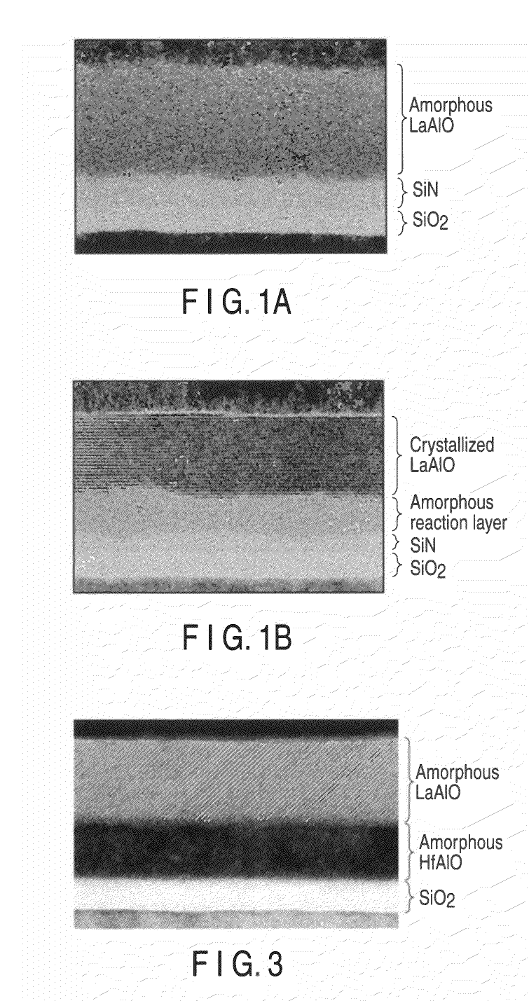

FIG. 1A shows a transmission electron microscope (TEM) image of the sectional structure of a stacked gate structure in which a tunnel insulating film made of silicon oxide (SiO₂), a charge storage layer made of amorphous silicon nitride (SiN), and a block insulating film made of amorphous lanthanum aluminate (LaAlO) are sequentially stacked on a silicon substrate. FIG. 1B shows a sectional TEM image after high-temperature annealing was performed at about 900° C. on this stacked gate structure.

FIGS. 1A and 1B indicate that the high-temperature annealing reduced the film thickness of the SiN film as the charge storage layer, and an amorphous reaction layer was formed by mixing or interdiffusion of lanthanum aluminate and silicon nitride. Also, FIG. 1B shows that the upper portion of lanthanum aluminate crystallized, so the film thickness was nonuniform. In addition, of the electrical characteristics obtained by the capacitance of this stacked gate structure, the effective oxide thickness (EOT) increased by about 2 nm by the high-temperature annealing. This reveals that the mutual reaction caused between the charge storage layer and block insulating film by the high-temperature annealing made the film structure nonuniform and degraded the electrical characteristics.

To solve the above problems, the present inventors used, as a charge storage layer, a crystallized high-k insulating material expected to have thermal stability higher than that of an amorphous film, thereby increasing the heat resistance of a stacked film including the charge storage layer and a block insulating film. In addition, since the dielectric constant of a crystallized high-k insulating material is generally higher than that in an amorphous state, the EOT may be further reduced. Embodiments of the present invention will be explained in detail below on the basis of the findings described above.

The embodiments of the present invention will be explained below with reference to the accompanying drawing. Note that in the following explanation, the same reference numerals denote elements having the same functions and arrangements, and a repetitive explanation will be made only when necessary.

### First Embodiment

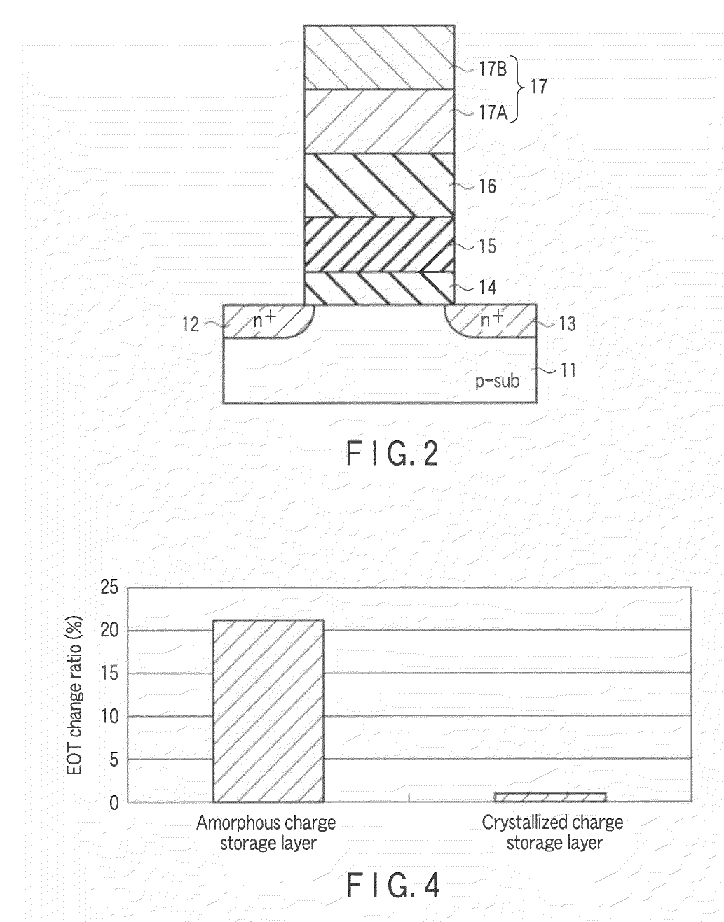

FIG. 2 is a sectional view illustrating the structure of a memory cell transistor (nonvolatile memory element) according to the first embodiment of the present invention.

A p-type substrate (p-sub) 11 is, e.g., a p-type semiconductor substrate, a semiconductor substrate having a p-type well, or a silicon-on-insulator (SOI) substrate having a p-type semiconductor layer. As the semiconductor substrate 11, silicon (Si) or a compound semiconductor such as SiGe, GaAs, or ZnSe is used.

A source region 12 and drain region 13 spaced apart from each other are formed in the semiconductor substrate 11. Each of the source region 12 and drain region 13 is an n⁺-type diffusion region formed by heavily doping an n⁺-type impurity (e.g., phosphorus [P], arsenic [As], or antimony [Sb]) in the semiconductor substrate 11.

A tunnel insulating film (tunneling layer) 14 made of silicon oxide about 4 nm thick is formed on the semiconductor substrate 11 between the source region 12 and drain region 13 (i.e., on a channel region). A charge storage layer (charge trapping layer) 15 made of crystallized hafnium aluminate about 10 nm thick is formed on the tunnel insulating film 14.

A block insulating film (blocking layer) 16 made of lanthanum aluminate about 10 to 20 nm thick is formed on the charge storage layer 15. A control gate electrode 17 is formed on the block insulating film 16. The control gate electrode 17 is formed by sequentially stacking a tantalum nitride layer 17A and tungsten layer 17B.

Details of the materials of the individual layers forming the memory cell transistor of this embodiment will be explained below.

As the tunnel insulating film 14, it is possible to use silicon oxide (SiO₂), silicon nitride (SiN), silicon oxynitride (SiON), or a stacked film of these compounds.

An example of the high-k insulating material used as the charge storage layer 15 is an oxide, nitride, or oxynitride containing at least one of hafnium (Hf), aluminum (Al), zirconium (Zr), titanium (Ti), and a rare-earth metal. The whole or a part of the charge storage layer 15 is crystallized.

An example of the high-k insulating material used as the block insulating film 16 is an oxide, oxynitride, silicate, or aluminate containing at least one rare-earth metal. The block insulating film 16 may be entirely or partially crystallized, and may also be amorphous. The block insulating film 16 is preferably crystallized because the heat resistance increases.

Note that the rare-earth metal includes La (lanthanum), Ce (cerium), Pr (praseodymium), Nd (neodymium), Pm (promethium), Sm (samarium), Eu (europium), Gd (gadolinium), Tb (terbium), Dy (dysprosium), Ho (holmium), Er (erbium), Tm (thulium), Yb (ytterbium), Lu (lutetium), Sc (scandium), and Y (yttrium).

As the control gate electrode 17A, it is possible to extensively use p⁺-type polysilicon, or a metal-based conductive material that is an element selected from the group consisting of gold (Au), platinum (Pt), cobalt (Co), beryllium (Be), nickel (Ni), rhodium (Rh), palladium (Pd), tellurium (Te), rhenium (Re), molybdenum (Mo), aluminum (Al), hafnium (Hf), tantalum (Ta), manganese (Mn), zinc (Zn), zirconium (Zr), indium (In), bismuth (Bi), ruthenium (Ru), tungsten (W), iridium (Ir), erbium (Er), lanthanum (La), titanium (Ti), and yttrium (Y), or a silicide, boride, nitride, or carbide containing one or more of these elements. The metal-based conductive material as the control gate electrode is particularly favorable because the material causes no depletion compared to a control gate electrode made of polysilicon, and hence the EOT can be decreased.

As the conductive layer 17B stacked on the control gate electrode 17A, it is possible to use a metal such as tungsten (W), or a low-resistance full silicide such as tungsten silicide, nickel silicide, or cobalt silicide.

The memory cell transistor of this embodiment is a so-called metal oxide nitride oxide semiconductor (MONOS) memory cell transistor using an insulator as the charge storage layer 15. The MONOS memory cell transistor captures and stores electric charge (electrons) in the charge storage layer 15. The ability to capture electric charge can be represented by the charge trap density. The higher the charge trap density, the larger the amount of electric charge that can be captured.

Electrons are injected from the channel region into the charge storage layer 15 or removed from the charge storage layer 15 to the channel region via the tunnel insulating film. The electrons injected into the charge storage layer are captured in traps of the charge storage layer 15. These electrons captured in the traps cannot easily escape from the traps, and stabilize. Since the threshold voltage of the memory cell transistor changes in accordance with the charge amount in the charge storage layer 15, data is stored in the memory cell transistor by discriminating between data “0” and data “1” in accordance with the level of the threshold voltage.

The result of an experimental check on the heat resistance increasing effect of the memory cell transistor of this embodiment having the above arrangement will be explained below. FIG. 3 shows a sectional TEM image after annealing was performed at about 900° C. on a stacked gate structure in which crystallized hafnium aluminate (HfAlO) as the charge storage layer 15 and amorphous lanthanum aluminate (LaAlO) as the block insulating film 16 were sequentially deposited on the tunnel insulating film 14 made of SiO₂. Hafnium aluminate (HfAlO) was deposited on the tunnel insulating film 14 made of SiO₂ by atomic layer deposition (ALD), and crystallized by high-temperature annealing at about 900° C. before lanthanum aluminate was deposited. As shown in FIG. 3, hafnium aluminate (HfAlO) maintained the crystallized state, and hardly changed the film thickness. In addition, lanthanum aluminate (LaAlO) crystallized and caused no interdiffusion between hafnium aluminate and lanthanum aluminate.

The EOT change ratios (%) before and after annealing were checked from the electrical characteristics of the memory cell transistors when crystallized hafnium aluminate was used as the charge storage layer (a crystallized charge storage layer) and amorphous silicon nitride was used as the charge storage layer (an amorphous charge storage layer) as a comparative example. FIG. 4 shows the results. As shown in FIG. 4, the EOT change ratio of the amorphous charge storage layer was 21%, and that of the crystallized charge storage layer was 1.0%. Accordingly, the use of the crystallized charge storage layer suppresses the mutual reaction caused between the charge storage layer and block insulating film by the high-temperature annealing. This suppresses the EOT change caused by the annealing, and makes it possible to form a memory cell transistor having a high thermal stability.

Also, the capacitance between the substrate 11 and control gate electrode 17 can be increased because the above-mentioned, high-k insulating material is used as the block insulating film 16. Accordingly, an operating voltage to be applied to the control gate electrode 17 can be decreased.

More specifically, an electric field to be applied to the tunnel insulating film 14 can be increased by increasing the capacitance of the block insulating film 16. This makes it possible efficiently inject or remove electric charge into or from the charge storage layer 15 with a low voltage.

As described previously, when the charge storage layer 15 is amorphous, the amorphous charge storage layer 15 and the block insulating film 16 containing a rare-earth metal cause mixing or interdiffusion, thereby changing the film thickness or degrading the electrical characteristics. In this embodiment, however, the charge storage layer 15 is crystallized before the block insulating film 16 is deposited. This makes it possible to prevent the change in film thickness of the block insulating film 16 or degradation of the electrical characteristics in the later annealing process.

An example of a method of manufacturing the memory cell transistor of this embodiment will be explained below with reference to the accompanying drawing.

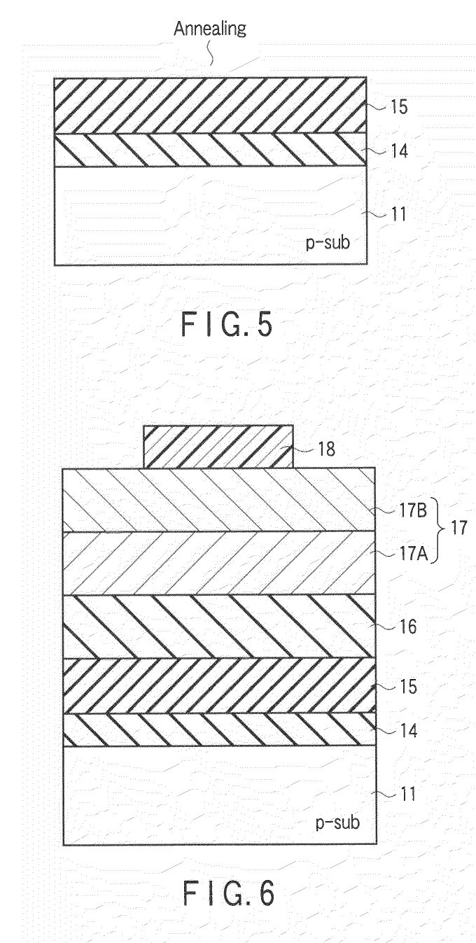

As shown in FIG. 5, a tunnel insulating film 14 made of silicon oxide about 4 nm thick is formed on a p-type semiconductor substrate 11 by using, e.g., thermal oxidation. Subsequently, a charge storage layer 15 made of hafnium aluminate about 10 nm thick is deposited on the tunnel insulating film 14 by using, e.g., ALD. Hafnium aluminate is then crystallized by annealing the sample at about 900° C.

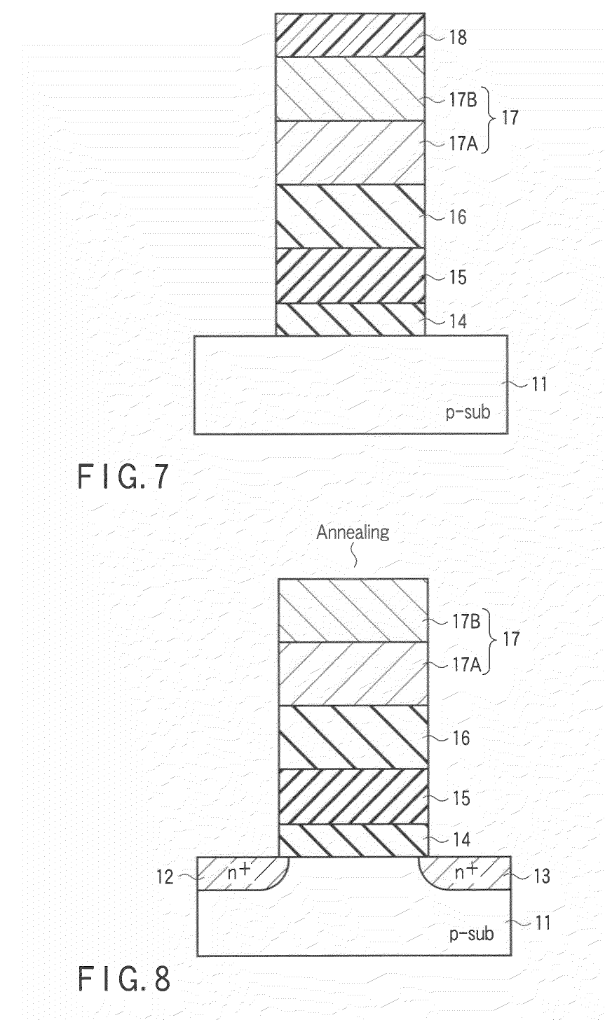

As shown in FIG. 6, a block insulating film 16 made of lanthanum aluminate about 10 to 20 nm thick is deposited on the charge storage layer 15 by using, e.g., ALD. A tantalum nitride layer 17A and tungsten layer 17B are sequentially deposited on the block insulating film 16 by using sputtering or the like, thereby forming a control gate electrode 17. To form a stacked gate structure having a desired planar shape, a resist layer 18 is formed on the control gate electrode 17 by lithography. Then, as shown in FIG. 7, the resist layer 18 is used as a mask to etch the stacked gate structure by reactive ion etching (RIE), thereby exposing the upper surface of the semiconductor substrate 11.

As shown in FIG. 8, impurity regions 12 and 13 are formed in the semiconductor substrate 11 by ion-implanting phosphorus (P) as a donor in the semiconductor substrate 11. After that, the resist layer 18 is removed. Finally, a source region 12 and drain region 13 are formed by activating the impurity regions by annealing the sample at about 900° C. This annealing step also crystallizes the block insulating film 16. In this manner, the memory cell transistor of this embodiment is formed.

In this embodiment as described in detail above, the use of the crystallized charge storage layer 15 makes it possible to suppress the mutual reaction caused between the charge storage layer 15 and block insulating film 16 by the high-temperature annealing. That is, after the charge storage layer 15 is deposited on the tunnel insulating film 14 and crystallized by annealing, the block insulating film 16 is deposited on the charge storage layer 15. Even when annealing for activating the impurity regions is performed, therefore, the mutual reaction between the charge storage layer 15 and block insulating film 16 is suppressed. Consequently, a memory cell transistor having a high thermal stability can be formed because the increase in EOT is suppressed.

Also, since the high-k insulating material described earlier is used as the block insulating film 16, the capacitance between the substrate 11 and control gate electrode 17 can be increased. This makes it possible to lower the operating voltage to be applied to the control gate electrode 17. Furthermore, since the mutual reaction between the charge storage layer 15 and block insulating film 16 is suppressed, it is possible to prevent the change in film thickness of the block insulating film 16 and degradation of the electrical characteristics.

Additionally, the heat resistance of the memory cell transistor can be further increased because the block insulating film 16 is also crystallized.

### Second Embodiment

In the second embodiment, an amorphous insulating layer is formed in the interface between a tunnel insulating film and crystallized charge storage layer. Since damage to a tunnel insulating film 14 can be reduced, degradation of the characteristics of the tunnel insulating film 14 can be reduced. This makes it possible to improve the characteristics of a memory cell transistor.

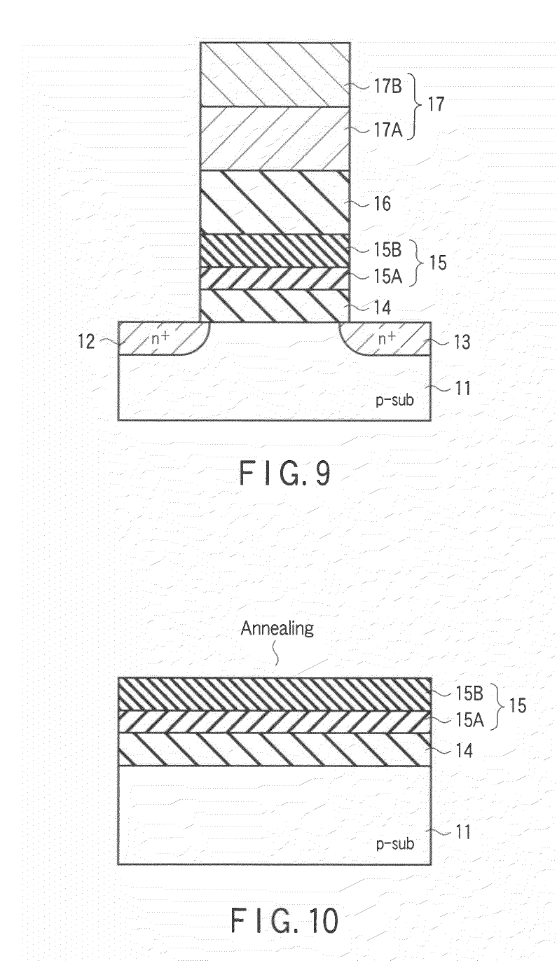

FIG. 9 is a sectional view illustrating the arrangement of a memory cell transistor according to the second embodiment of the present invention.

A source region 12 and drain region 13 spaced apart from each other are formed in a semiconductor substrate 11. A tunnel insulating film 14 made of silicon oxide about 4 nm thick is formed on the semiconductor substrate 11 between the source region 12 and drain region 13 (i.e., on a channel region). A charge storage layer 15 is formed on the tunnel insulating film 14 by stacking a first insulating layer 15A made of silicon nitride about 5 nm thick, and a high-k second insulating layer 15B made of crystallized hafnium aluminate about 10 nm thick.

The first insulating layer 15A of the charge storage layer 15 is in an amorphous state, and made of, e.g., silicon nitride. The second insulating layer 15B of the charge storage layer 15 is made of the same material as that of the charge storage layer 15 disclosed in the first embodiment.

A block insulating film 16 made of lanthanum aluminate about 10 to 20 nm thick is formed on the charge storage layer 15. The block insulating film 16 may be entirely or partially crystallized, and may also be amorphous. The block insulating film 16 is preferably crystallized because the heat resistance increases.

A control gate electrode 17 is formed on the block insulating film 16. The control gate electrode 17 is formed by sequentially stacking a tantalum nitride layer 17A and tungsten silicide layer 17B.

The first insulating layer 15A of the charge storage layer 15 has a function as a charge storage layer, and also has a function as a barrier layer. Damage to the tunnel insulating film 14 can be reduced further when the barrier layer 15A is formed between the tunnel insulating film 14 and hafnium aluminate 15B than when the hafnium aluminate 15B is directly formed on the tunnel insulating film 14. This makes it possible to reduce degradation of the characteristics of the tunnel insulating film 14, and reduce degradation of the characteristics of the memory cell transistor as well.

An example of a method of manufacturing the memory cell transistor of this embodiment will be explained below with reference to the accompanying drawing.

As shown in FIG. 10, a tunnel insulating film 14 made of silicon oxide about 4 nm thick is formed on a p-type semiconductor substrate 11 by using, e.g., thermal oxidation. Subsequently, a first insulating layer 15A made of silicon nitride about 5 nm thick is deposited on the tunnel insulating film 14 by using, e.g., chemical vapor deposition (CVD). A high-k second insulating layer 15B made of hafnium aluminate about 10 nm thick is deposited on the first insulating layer 15A by using, e.g., ALD. The second insulating layer 15B is then crystallized by annealing the sample at about 900° C.

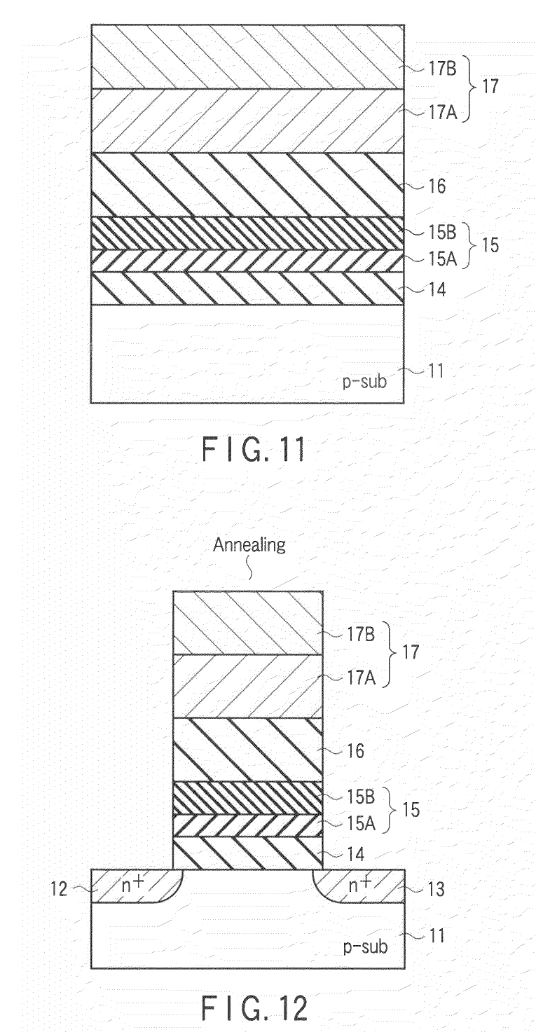

As shown in FIG. 11, a block insulating film 16 made of lanthanum aluminate about 10 to 20 nm thick is deposited on a charge storage layer 15 by using, e.g., ALD. A tantalum nitride layer 17A is deposited on the block insulating film 16 by using sputtering or the like. A polysilicon layer 17B is deposited on the tantalum nitride layer 17A by using, e.g., CVD. Then, a tungsten film (not shown) is deposited on the polysilicon layer 17B by CVD using W(CO)₆ as a source gas. The polysilicon layer 17B is converted into tungsten silicide in a later annealing step.

As shown in FIG. 12, the stacked gate structure is patterned by lithography and RIE. Subsequently, impurity regions 12 and 13 are formed in the semiconductor substrate 11 by ion-implanting phosphorus (P) as a donor in the semiconductor substrate 11. Finally, a source region 12 and drain region 13 are formed by activating the impurity regions by annealing the sample at about 900° C. This annealing step also crystallizes the block insulating film 16. In this way, the memory cell transistor of this embodiment is formed.

In this embodiment as described in detail above, it is possible to prevent the high-k second insulating layer 15B made of, e.g., hafnium aluminate from diffusing to the tunnel insulating film 14 by the high-temperature annealing. Since degradation of the characteristics of the tunnel insulating film 14 can be reduced, leakage currents from the charge storage layer 15 to the semiconductor substrate 11 can be reduced. Consequently, degradation of the characteristics of the memory cell transistor can be reduced.

Also, the use of the crystallized second insulating layer 15B makes it possible to suppress the mutual reaction caused between the charge storage layer 15 and block insulating film 16 by the high-temperature annealing. Other effects are the same as those of the first embodiment.

### Third Embodiment

In the third embodiment, a charge storage layer is formed such that an amorphous insulating layer contains a crystallized granular high-k insulating layer. The mutual reaction between the charge storage layer and a block insulating film is suppressed by forming the crystallized granular high-k insulating layer in the interface to the block insulating film.

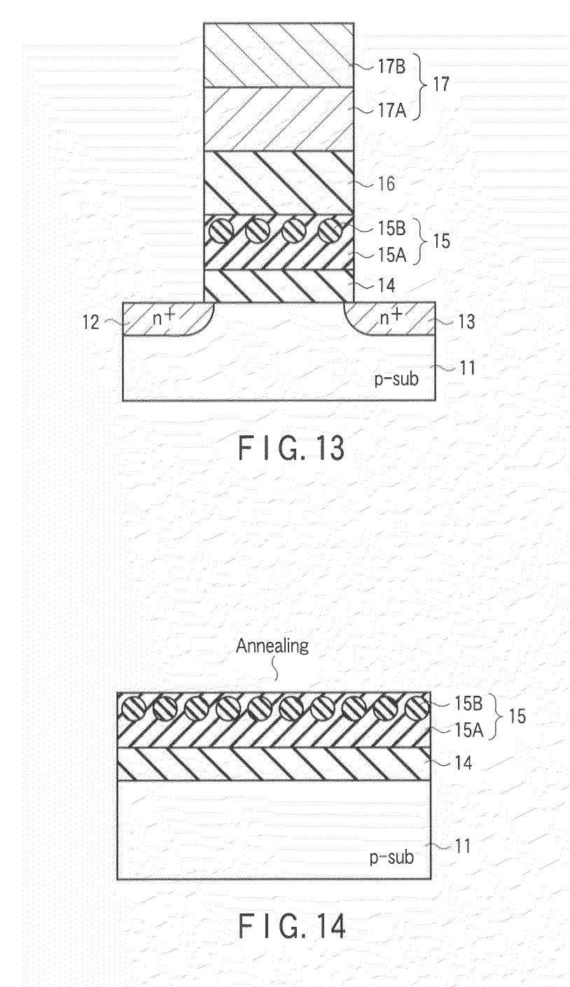

FIG. 13 is a sectional view illustrating the arrangement of a memory cell transistor according to the third embodiment of the present invention.

A source region 12 and drain region 13 spaced apart from each other are formed in a semiconductor substrate 11. A tunnel insulating film 14 made of silicon oxide about 4 nm thick is formed on the semiconductor substrate 11 between the source region 12 and drain region 13 (i.e., on a channel region). A charge storage layer 15 about 10 nm thick is formed on the tunnel insulating film 14. In the charge storage layer 15, a plurality of dots 15B (a granular high-k insulating layer 15B) made of crystallized titanium oxide having a diameter of about 2 to 5 nm are formed in an insulating layer 15A made of silicon nitride. The dots 15B are formed near the interface to a block insulating film 16 (to be described later).

The insulating layer 15A of the charge storage layer 15 is in an amorphous state, and made of, e.g., silicon nitride. The granular insulating layer 15B of the charge storage layer 15 is made of the same material as that of the charge storage layer 15 disclosed in the first embodiment.

A block insulating film 16 made of lanthanum aluminate about 10 to 20 nm thick is formed on the charge storage layer 15. A control gate electrode 17 is formed on the block insulating film 16. The control gate electrode 17 is formed by sequentially stacking a tantalum carbide layer 17A and tungsten layer 17B.

In the memory cell transistor having the above arrangement, the plurality of dots 15B made of crystallized titanium oxide are formed near the interface to the block insulating film 16, so the mutual reaction between the charge storage layer 15 and block insulating film 16 can be suppressed.

An example of a method of manufacturing the memory cell transistor of this embodiment will be explained below with reference to the accompanying drawing.

As shown in FIG. 14, a tunnel insulating film 14 made of silicon oxide about 4 nm thick is formed on a p-type semiconductor substrate 11 by using, e.g., thermal oxidation. Subsequently, an insulating layer 15A made of silicon nitride about 10 nm thick is deposited on the tunnel insulating film 14 by using, e.g., CVD. A thin titanium oxide film about 5 nm thick is deposited on the insulating layer 15A by using, e.g., ALD. Then, a plurality of dots 15B made of crystallized titanium oxide having a diameter of about 2 to 5 nm are formed in the insulating layer 15A by annealing the sample at about 900° C.

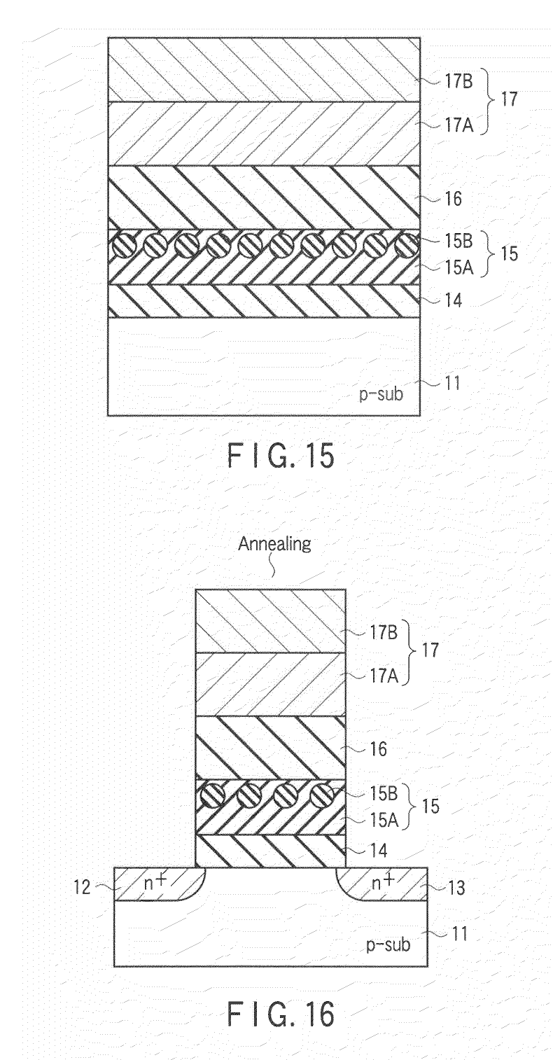

As shown in FIG. 15, a block insulating film 16 made of lanthanum aluminate about 10 to 20 nm thick is deposited on a charge storage layer 15 by using, e.g., ALD. A control gate electrode 17 is formed on the block insulating film 16 by sequentially depositing a tantalum carbide layer 17A and tungsten layer 17B by sputtering or the like.

As shown in FIG. 16, the stacked gate structure is patterned by lithography and RIE. Subsequently, impurity regions 12 and 13 are formed in the semiconductor substrate 11 by ion-implanting phosphorus (P) as a donor in the semiconductor substrate 11. Finally, a source region 12 and drain region 13 are formed by activating the impurity regions by annealing the sample at about 900° C. This annealing step also crystallizes the block insulating film 16. In this way, the memory cell transistor of this embodiment is formed.

In this embodiment as described in detail above, the plurality of crystallized dots 15B are formed near the interface to the block insulating film 16. Accordingly, the mutual reaction between the charge storage layer 15 and block insulating film 16 can be suppressed.

Also, since the insulating layer 15A made of silicon nitride is formed on the tunnel insulating film 14, damage inflicted on the tunnel insulating film 14 by the high-temperature annealing can be reduced. As a consequence, degradation of the characteristics of the tunnel insulating film 14 can be reduced. Other effects are the same as those of the first embodiment.

Note that each of the above embodiments is explained by taking an enhanced structure in which the source/drain regions are n-type and the channel region is p-type. However, the present invention is not limited to this, and it is also possible to use a depleted structure in which the source/drain regions are n-type and the channel is also n-type. Furthermore, the present invention is not limited to a bulk semiconductor substrate, and a silicon-on-insulator (SOI) substrate may also be used.

Also, although each embodiment uses a silicon substrate as an example of a semiconductor substrate, it is also possible to apply the present invention to any semiconductor substrate and any transistor structure. Examples are a polysilicon substrate, fin substrate, and stacked MONOS. In addition, the memory cell transistors of the above embodiments can be applied to, e.g., a NAND, NOR, AND, divided bit-line NOR (DINOR), NANO, or ORNAND memory cell array.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile memory element comprising:
a semiconductor region;
a source region and a drain region provided in the semiconductor region;
a tunnel insulating layer provided on the semiconductor region between the source region and the drain region;
a charge storage layer provided on the tunnel insulating layer;
a block insulating layer provided on the charge storage layer; and
a control gate electrode provided on the block insulating layer,
wherein the charge storage layer includes one of an oxide, a nitride and an oxynitride, which contains at least one material selected from the group consisting of Hf, Al, Zr, Ti and a rare-earth metal, and is entirely or partially crystallized, and
the block insulating layer includes one of an oxide, an oxynitride, a silicate and an aluminate, which contains at least one rare-earth metal.

2. The element according to claim 1, wherein the block insulating layer is entirely or partially crystallized.

3. The element according to claim 1, wherein the charge storage layer includes a first insulating layer which is provided in an interface to the tunnel insulating layer and is amorphous.

4. The element according to claim 3, wherein the first insulating layer includes silicon nitride.

5. A nonvolatile memory element comprising:
a semiconductor region;
a source region and a drain region provided in the semiconductor region;
a tunnel insulating layer provided on the semiconductor region between the source region and the drain region;
a charge storage layer including a first insulating layer which is provided on the tunnel insulating layer and is amorphous, and a second insulating layer which is granularly formed in the first insulating layer and crystallized;
a block insulating layer provided on the charge storage layer; and
a control gate electrode provided on the block insulating layer,
wherein the second insulating layer includes one of an oxide, a nitride and an oxynitride, which contains at least one material selected from the group consisting of Hf, Al, Zr, Ti and a rare-earth metal, and is entirely or partially crystallized, and the block insulating layer includes one of an oxide, an oxynitride, a silicate and an aluminate, which contains at least one rare-earth metal.

6. The element according to claim 5, wherein the second insulating layer is provided in an interface to the block insulating layer.

7. The element according to claim 5, wherein the first insulating layer includes silicon nitride.

8. A method of manufacturing a nonvolatile memory element, comprising:
forming a tunnel insulating layer on a semiconductor region;
forming a charge storage layer on the tunnel insulating layer;
crystallizing the charge storage layer by performing first annealing;
forming a block insulating layer on the charge storage layer;
forming a control gate electrode on the block insulating layer;
forming an impurity region in the semiconductor region by doping an impurity in the semiconductor region; and
activating the impurity region by performing second annealing.

9. The method according to claim 8, wherein the second annealing crystallizes the block insulating layer.

10. The method according to claim 8, wherein the charge storage layer includes one of an oxide, a nitride and an oxynitride, which contains at least one material selected from the group consisting of Hf, Al, Zr, Ti and a rare-earth metal, and is entirely or partially crystallized.

11. The method according to claim 8, wherein the block insulating layer includes one of an oxide, an oxynitride, a silicate and an aluminate, which contains at least one rare-earth metal.

12. The method according to claim 8, further comprising forming an amorphous insulating layer, after forming the tunnel insulating layer.

13. The method according to claim 12, wherein the insulating layer includes silicon nitride.
